(19) United States
(12) Patent Application Publication
(10) Pub. No.: US 2019/0029140 A1
(43) Pub. Date: Jan. 24, 2019

(54) DC-DC CONVERTER

(71) Applicant: Yazaki Corporation, Tokyo (JP)

(72) Inventors: Kazuhisa WATARU, Makinohara-shi (JP); Minoru KUBOTA, Makinohara-shi (JP)

(73) Assignee: Yazaki Corporation, Tokyo (JP)

(21) Appl. No.: 16/017,237

(22) Filed: Jun. 25, 2018

(30) Foreign Application Priority Data
Jul. 19, 2017 (JP) 2017-139636

(51) Int. Cl. H05K 7/20; H05K 1/02

(52) U.S. Cl. CPC H05K 7/209; H02M 3/00; H05K 1/0203

(57) ABSTRACT

Provided is a DC-DC converter including a substrate to which a heat sink is attached, a first terminal and a second terminal connected to different DC power source systems, respectively, a circuit part formed on the substrate and performing DC-DC voltage conversion, a first bus bar as a current path between the first terminal and the circuit part, and a second bus bar as a current path between the second terminal and the circuit part.

### CROSS REFERENCE TO RELATED APPLICATION

The priority application Japanese Patent Application No. 2017-139636 upon which this patent application is based is hereby incorporated by reference.

### BACKGROUND OF THE INVENTION

### Field of the Invention

The present disclosure relates to a DC-DC converter including a heat sink.

### Description of the Related Art

In recent years, an automobile and such is mounted with two power source systems with different voltages. For example, in addition to a conventional 12V power source system, a 48V power source system is mounted.

In case where the two power source systems with different voltages are mounted, if power can be mutually transmitted between the two power source systems, one of the two power source systems can compensate power for the other one of the two power source systems when the other one of the two power source systems goes down, for example. It is also possible to charge a battery of one of the power source systems from a battery of the other one of the power source systems. Thus, it is proposed to use a bidirectional DC-DC converter to perform the mutual transmission of power (for example, refer to Japan Patent Application Publication No. 2016-226199).

### SUMMARY OF THE INVENTION

FIG. 5 shows a bidirectional DC-DC converter 300 used in an automobile and such. As shown, the DC-DC converter 300 is arranged on a substrate 310 and includes, in the same plane, a first terminal 321, a second terminal 322, a ground terminal 323, a first current line 331, a second current line 332 and a circuit part 338. The substrate 310 is provided with a heat sink 340 which is attached, via a thermal interface material (TIM) 341 as a heat conductive material, to a surface of the substrate 310 on opposite side of the circuit part formation surface.

The first terminal 321 is connected to a first power source system, and the second terminal 322 is connected to a second power source system. The first current line 331 is a current path between the first terminal 321 and the circuit part 338, and the second current line 332 is a current path between the second terminal 322 and the circuit part 338. The first current line 331 and the second current line 332 are used for large current and are routed with copper foil on the substrate 310. The ground terminal 323 is used in common for the first power source system and the second power source system.

Because the DC-DC converter 300 used in the automobile and such deals with large current, the first current line 331, the second current line 332 and the circuit part 338 generate heat with the operation of the DC-DC converter 300, causing an increase in temperature of the entire substrate 310. To address this, the heat sink 340 attached via the TIM 341 is provided for heat dissipation. However, since the increase in temperature may affect the stability and lifetime of the circuit, there is a need for further improvement in the heat dissipation performance.

An object of the present invention is to improve heat dissipation performance in a DC-DC converter.

To achieve the above-mentioned object, a DC-DC converter according to one embodiment of the present invention includes a substrate to which a heat sink is attached, a first terminal and a second terminal connected to different DC power source systems, respectively, a circuit part formed on the substrate and performing DC-DC voltage conversion, a first bus bar as a current path between the first terminal and the circuit part, and a second bus bar as a current path between the second terminal and the circuit part. According to this embodiment, heat can be dissipated not only from the heat sink but also from the first bus bar and the second bus bar, thereby improving the heat dissipation performance of the DC-DC converter.

Further, according to the DC-DC converter of this embodiment, the first bus bar and the second bus bar are formed of a metal plate having a rectangular shape, and are attached, in a standing position and with a long side of the bus bars positioned on the substrate side, to a circuit part formation face of the substrate on which the circuit part is formed. Consequently, since both of the wide plate surfaces of the first bus bar and the second bus bar are exposed above the substrate, the heat can be dissipated with high efficiency. Further, the area of the substrate can be reduced.

According to the present invention, the heat dissipation performance can be improved in the DC-DC converter.

### BRIEF DESCRIPTION OF THE DRAWINGS

FIG. 1 is a perspective view illustrating a configuration of a DC-DC converter according to one embodiment of the present invention;

FIG. 2 is a perspective view showing the DC-DC converter viewed from a first terminal side;

FIG. 3 is a cross-sectional view taken along a A-A line of the DC-DC converter in FIGS. 1 and 2;

FIG. 4 is an illustration for comparing in size a conventional DC-DC converter with the DC-DC converter of the present embodiment; and

FIG. 5 is a perspective view illustrating a configuration of the conventional DC-DC converter.

### DETAILED DESCRIPTION OF AN EXEMPLARY EMBODIMENT OF THE INVENTION

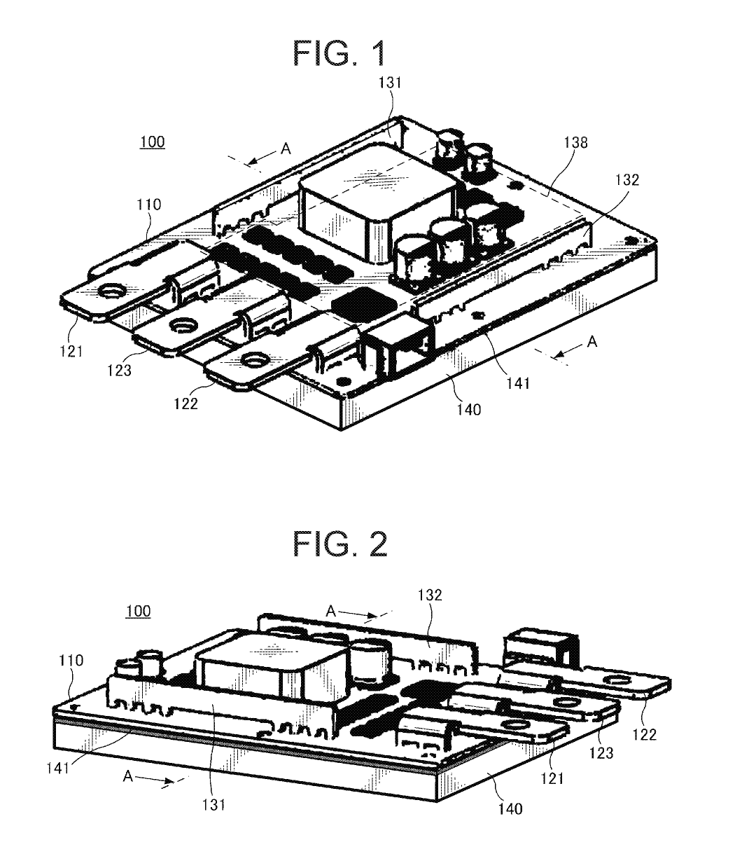

The following will explain an exemplary embodiment of the present invention with reference to the drawings. FIG. 1 is a perspective view illustrating a configuration of a DC-DC converter 100 according to this embodiment. The DC-DC converter 100 performs a bidirectional transmission of power between a first direct current power source system and a second direct current power source system. However, the present invention may also be applied to a unidirectional DC-DC converter. Further, the present invention may also be applied to one of a boost DC-DC converter and a buck DC-DC converter or may also be applied to an isolated DC-DC converter.

As shown in FIG. 1, the DC-DC converter 100 is arranged on a substrate 110, and includes a first terminal 121, a second terminal 122, a ground terminal 123 and a circuit part 138 which are arranged in the same plane. The first terminal 121 and the second terminal 122 are external terminals connected to a first power source system and a second power source system, respectively.

The circuit part 138 performs DC-DC voltage conversion. The circuit part 138 may use any voltage conversion system. For example, a linear regulator system, a chopper circuit system, a switching regulator system and such, may be used.

A heat sink 140 is attached, via a thermal interface material (TIM) 141 as a heat conductive material, on a surface of the substrate 110 on opposite side of a circuit part formation surface (i.e., the surface of the substrate on which the circuit part is formed). The thermal interface material 141 may be silicon, graphite, rubber, thermal conductive grease, metal and such. The heat sink 140 may be constituted of a metal material with low thermal resistance, and it is preferable that the heat sink has a fin-shape so that it has a large surface area. A fan may be attached to the heat sink to improve the heat dissipation effect.

In this embodiment, a first bus bar 131 as a current path is provide between the first terminal 121 and the circuit part 138, and a second bus bar 132 as a current path is provided between the second terminal 122 and the circuit part 138.

The first bus bar 131 and the second bus bar 132 are both formed of a long, thin rectangular-shaped metal plate, and are attached to the circuit part formation surface of the substrate 110 in a standing position and with the long side of the bus bars positioned downward (i.e., the long side adjacent to the substrate 110 side). Thus, both wide plate surfaces of the respective first and second bus bars are exposed above the substrate 110. Further, since the first and second bus bars are in the standing position, the attachment area on the substrate 110 can be small.

The attachment of the first bus bar 131 and the second bus bar 132 to the substrate 110 may be performed by forming a plurality of legs to each bus bar on its long side on one side of the metal plate and fitting the legs into holes formed on the substrate 110, as shown in FIG. 2. FIG. 2 is a perspective view seen from the first terminal 121 side.

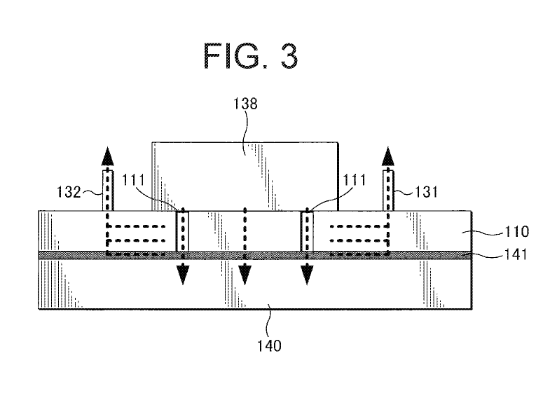

FIG. 3 is a cross-sectional view taken along the A-A line of the DC-DC converter 100 of FIG. 1 and FIG. 2. As shown, the heat generated from the circuit part 138 is conducted to the substrate 110 and VIA holes 111 and conducted to the heat sink 140 via the TIM 141 and dissipated.

Further, in this embodiment, the heat generated from the circuit part 138 is also dissipated from the first bus bar 131 and the second bus bar 132 connected via the substrate 110. As described above, since both of the wide plate surfaces of the first bus bar 131 and the second bus bar 132 are exposed above the substrate 110, the heat can be dissipated with high efficiency. Further, the first bus bar 131 and the second bus bar 132 can dissipate heat generated on themselves.

As described above, according to the DC-DC converter 100 of this embodiment, the heat is dissipated efficiently not only from the heat sink 140 on the opposite face side of the circuit part 138 but also from the first bus bar 131 and the second bus bar 132 provided on the same face side with the circuit part 138. Consequently, the heat dissipation performance can be improved.

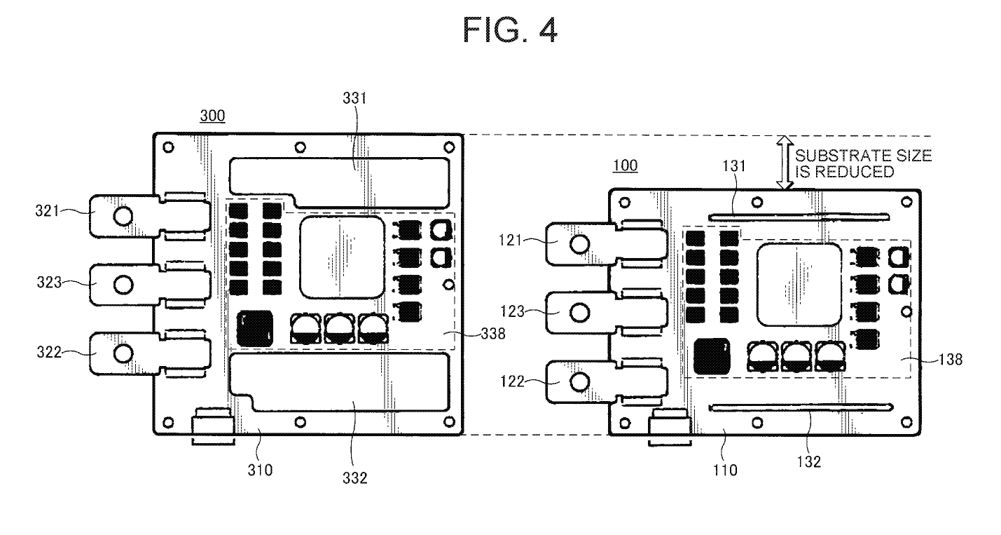

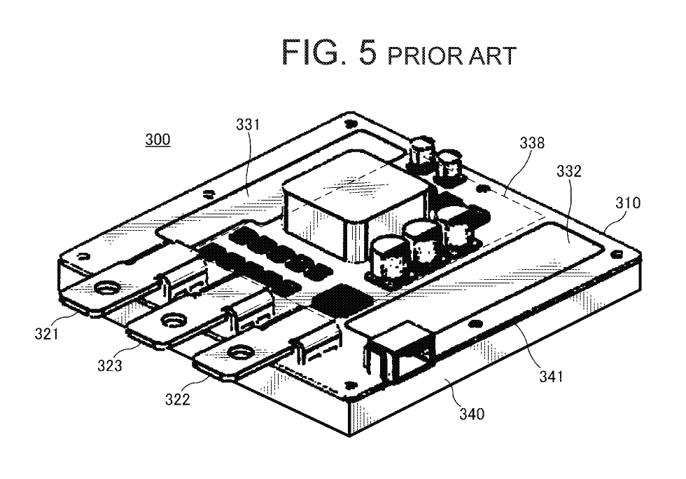

The DC-DC converter 100 of this embodiment uses, as the current paths, the first bus bar 131 and the second bus bar 132 with their metal plates in the standing position, instead of the conventional first current line 331 and the second current line 332 routed with copper foil. Consequently, as shown in FIG. 4, according to his embodiment, the area of the circuit part 138 is the same as the conventional circuit part 338, but the size of the substrate 110 can be reduced, which provides further advantageous effect.

The present invention is not limited to the above-described embodiment. For example, the ground line may be formed using the metal plate bus bar. Further, a fin may be formed on the metal plate constituting the first bus bar 131 and the second bus bar 132, or the metal plates of the bus bars may be folded.

### LIST OF REFERENCE SIGNS

100 DC-DC converter
110 substrate
111 VIA hole
121 first terminal
122 second terminal
123 ground terminal
131 first bus bar
132 second bus bar
138 circuit part
140 heat sink
141 thermal interface material

What is claimed is:

1. A DC-DC converter comprising:
a substrate to which a heat sink is attached;
a first terminal and a second terminal connected to different DC power source systems, respectively;
a circuit part formed on the substrate and performing DC-DC voltage conversion;
a first bus bar as a current path between the first terminal and the circuit part; and
a second bus bar as a current path between the second terminal and the circuit part.

2. The DC-DC converter according to claim 1,
wherein the first bus bar and the second bus bar are formed of a metal plate having a rectangular shape, and
wherein the first bus bar and the second bus bar are attached, in a standing position and with a long side of the bus bars positioned on the substrate side, to a circuit part formation face of the substrate on which the circuit part is formed.
